(19) United States
(12) Patent Application Publication
(10) Pub. No.: US 2024/0273263 A1
(43) Pub. Date: Aug. 15, 2024

(54) ENTITY-LEVEL COHORT FORCASTING AND SIMULATION INTERFACES

(71) Applicant: Optum Services (Ireland) Limited, Dublin (IE)

(72) Inventors: Donald W. James, Costa Mesa, CA (US); Michael J. McCarthy, Dublin (IE); Kieran O'Donoghue, Dublin (IE); Denise M. Nagel, Menomonie, WI (US)

(21) Appl. No.: 18/486,772

(22) Filed: Oct. 13, 2023

Related U.S. Application Data
(60) Provisional application No. 63/484,227, filed on Feb. 10, 2023.

(51) Int. Cl. G06F 30/27

(52) U.S. Cl. CPC G06F 30/27

(57) ABSTRACT

Various embodiments of the present disclosure provide cohort prediction and activity forecasting techniques for implementing improved population analytics in various prediction domains. The techniques may include generating a documented parameter rate for an entity cohort and a predicted parameter rate for the entity cohort based on a plurality of entity-specific parameter scores. The techniques include generating a predicted documentation error for the entity cohort based on a comparison between the documented parameter rate and the predicted parameter rate and, responsive to the predicted documentation error, initiating, using one or more cohort-specific causal models, the performance of an error correction action for the entity cohort.

### CROSS-REFERENCE TO RELATED APPLICATIONS

This application claims the benefit of U.S. Provisional Application No. 63/484,227, entitled “Estimating, Tracking, And Projecting Patient Risk With Scenario Modeling,” and filed Feb. 10, 2023, the entire contents of which are herein incorporated by reference.

### BACKGROUND

Various embodiments of the present disclosure address technical challenges related to cohort prediction and activity forecasting techniques for diverse cohort prediction domains. The techniques of the present disclosure may be applied in any of a number of different prediction domains. As one example, some of the techniques of the present disclosure may address technical challenges related to predicting illness burdens of a population where the accuracy of such predictions is paramount for establishing infrastructure and allocating resources appropriately. Traditional methods for understanding illness burdens are limited to historical data for a statically defined cohort of patients. This may lead to inaccuracies due to a number of factors including a lack of medical history for new members, inefficient coding for existing members, dynamically changing memberships, and new emerging chronic diseases that manifest at different rates. These factors, among others, present technical and practical challenges that have traditionally prevented cohort prediction and activity forecasting techniques from accurately predicting what a patient illness burden will be (expected risk) and then dynamically tracking the expected risk against an actually recorded risk over time. These deficiencies further prevent the identification of underperformance within a cohort and the optimal selection of actions to mitigate against underperformance.

Some techniques have been proposed for addressing these challenges. Existing capabilities, for example, may apply processes and analytics that forecast and track the expected parameter risks at a general population level. For example, there are existing actuarial processes that may support the creation of bids and that create revenue projections and financial forecasts. However, these tools rely primarily on trending previously reported data. While this may be relatively effective over large populations over large periods of time, it lacks the specificity and flexibility to handle real time changes in approaches and membership. And, because traditional techniques work in broad brush strokes across a population, they are often ineffective for planning specific prediction-based actions for targeted entity cohorts, and for projecting what the likely impact of such actions will be.

Various embodiments of the present disclosure make important contributions to traditional cohort prediction and activity forecasting techniques by addressing these technical challenges, among others.

### BRIEF SUMMARY

Various embodiments of the present disclosure provide cohort prediction and activity forecasting techniques that improve traditional forecasting techniques by enabling granular cohort-level predictions for dynamically changing entity cohorts. For example, some techniques of the present disclosure enable new processes for predicting a predicted parameter rate for an entity cohort at the beginning of a time interval. Unlike traditional techniques, the predicted parameter rate may be generated based on entity-level predictions that allow for entity cohorts of dynamically changing sizes and other cohort defining criteria. The resulting predicted parameter rates may be leveraged to track documentation errors within various different entity cohorts to identify optimal intervention opportunities across a diverse population of entities. When applied to a clinical domain, some of the techniques of the present disclosure enable the initiation of prediction-based actions, such as error correction actions, that are tailored to subsets of members within a population to improve documentation gaps within a healthcare system.

In some embodiments, a computer-implemented method includes generating, by one or more processors, a documented parameter rate for an entity cohort; generating, by the one or more processors and using a machine learning prediction model, a plurality of entity-specific parameter scores for the entity cohort; generating, by the one or more processors, a predicted parameter rate for the entity cohort based on the plurality of entity-specific parameter scores for the entity cohort; generating, by the one or more processors, a predicted documentation error for the entity cohort based on a comparison between the documented parameter rate and the predicted parameter rate; and responsive to the predicted documentation error, initiating, by the one or more processors and using one or more cohort-specific causal models, the performance of an error correction action for the entity cohort.

In some embodiments, a computing system includes memory and one or more processors communicatively coupled to the memory, the one or more processors are configured to generate a documented parameter rate for an entity cohort; generate, using a machine learning prediction model, a plurality of entity-specific parameter scores for the entity cohort; generate a predicted parameter rate for the entity cohort based on the plurality of entity-specific parameter scores for the entity cohort; generate a predicted documentation error for the entity cohort based on a comparison between the documented parameter rate and the predicted parameter rate; and responsive to the predicted documentation error, initiate, using one or more cohort-specific causal models, the performance of an error correction action for the entity cohort.

In some embodiments, one or more non-transitory computer-readable storage media include instructions that, when executed by one or more processors, cause the one or more processors to generate a documented parameter rate for an entity cohort; generate, using a machine learning prediction model, a plurality of entity-specific parameter scores for the entity cohort; generate a predicted parameter rate for the entity cohort based on the plurality of entity-specific parameter scores for the entity cohort; generate a predicted documentation error for the entity cohort based on a comparison between the documented parameter rate and the predicted parameter rate; and responsive to the predicted documentation error, initiate, using one or more cohort-specific causal models, the performance of an error correction action for the entity cohort.

### BRIEF DESCRIPTION OF THE DRAWINGS

FIG. 1 illustrates an example computing system in accordance with one or more embodiments of the present disclosure.

FIG. 2 is a schematic diagram showing a system computing architecture in accordance with one or more embodiments of the present disclosure.

FIG. 3 is a dataflow diagram showing example data structures and modules for generating predictive insights for an entity cohort in accordance with some embodiments discussed herein.

FIG. 4 is an exemplary diagram of a user interface in accordance with some embodiments discussed herein.

FIG. 5 is a flowchart showing an example of an entity cohort evaluation process in accordance with some embodiments discussed herein.

### DETAILED DESCRIPTION

Various embodiments of the present disclosure are described more fully hereinafter with reference to the accompanying drawings, in which some, but not all embodiments of the present disclosure are shown. Indeed, the present disclosure may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Terms such as “computing,” “determining,” “generating,” and/or similar words are used herein interchangeably to refer to the creation, modification, or identification of data. Further, “based on,” “based at least in part on,” “based at least on,” “based upon,” and/or similar words are used herein interchangeably in an open-ended manner such that they do not indicate being based only on or based solely on the referenced element or elements unless so indicated. Like numbers refer to like elements throughout. Moreover, while certain embodiments of the present disclosure are described with reference to predictive data analysis, one of ordinary skills in the art will recognize that the disclosed concepts may be used to perform other types of data analysis.

### I. Computer Program Products, Methods, and Computing Entities

Embodiments of the present disclosure may be implemented in various ways, including as computer program products that comprise articles of manufacture. Such computer program products may include one or more software components including, for example, software objects, methods, data structures, or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query, or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together, such as in a particular directory, folder, or library. Software components may be static (e.g., pre-established, or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably).

Such non-transitory computer-readable storage media include all computer-readable media (including volatile and non-volatile media).

In some embodiments, a non-volatile computer-readable storage medium may include a floppy disk, flexible disk, hard disk, solid-state storage (SSS) (e.g., a solid-state drive (SSD), solid state card (SSC), solid state module (SSM), enterprise flash drive, magnetic tape, or any other non-transitory magnetic medium, and/or the like). A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In some embodiments, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for, or used in addition to, the computer-readable storage media described above.

As should be appreciated, various embodiments of the present disclosure may also be implemented as methods, apparatuses, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatuses, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some example embodiments, retrieval, loading, and/or execution may be performed in parallel such that multiple instructions are retrieved, loaded, and/or executed together. Thus, such embodiments may produce specifically configured machines performing the steps or operations specified in the block diagrams and flowchart illustrations. Accordingly, the block diagrams and flowchart illustrations support various combinations of embodiments for performing the specified instructions, operations, or steps.

### II. Example Framework

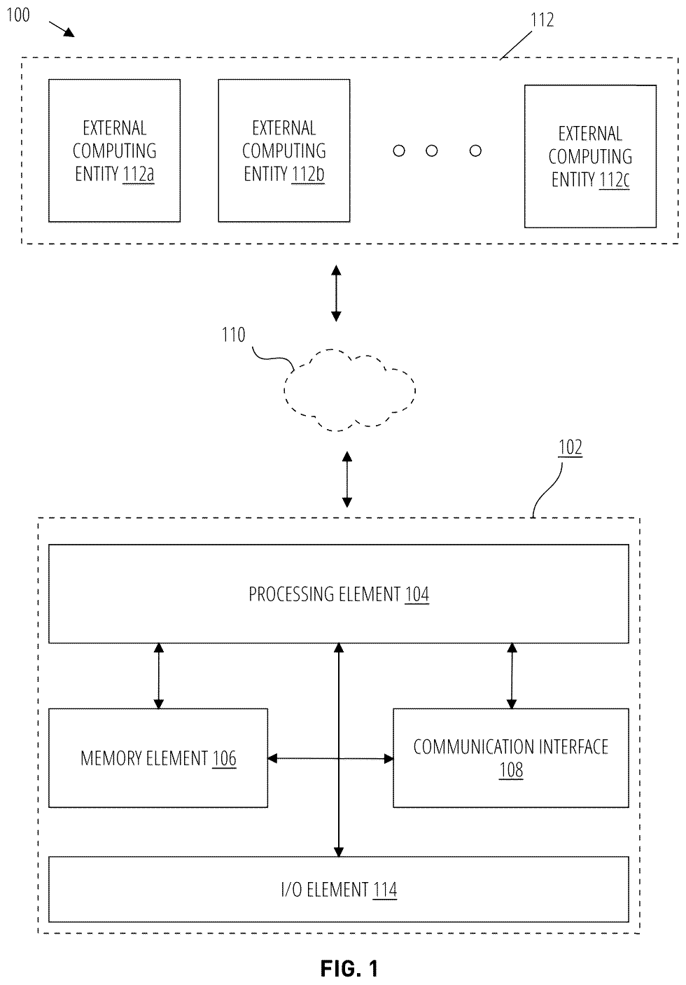

FIG. 1 illustrates an example computing system 100 in accordance with one or more embodiments of the present disclosure. The computing system 100 may include a predictive computing entity 102 and/or one or more external computing entities 112a-c communicatively coupled to the predictive computing entity 102 using one or more wired and/or wireless communication techniques. The predictive computing entity 102 may be specially configured to perform one or more steps/operations of one or more techniques described herein. In some embodiments, the predictive computing entity 102 may include and/or be in association with one or more mobile device(s), desktop computer(s), laptop(s), server(s), cloud computing platform(s), and/or the like. In some example embodiments, the predictive computing entity 102 may be configured to receive and/or transmit one or more datasets, objects, and/or the like from and/or to the external computing entities 112a-c to perform one or more steps/operations of one or more techniques (e.g., prediction and forecasting techniques, simulation techniques, visualization techniques, and/or the like) described herein.

The external computing entities 112a-c, for example, may include and/or be associated with one or more entities that may be configured to receive, store, manage, and/or facilitate datasets, such as historical datasets, entity datasets, and/or the like. The external computing entities 112a-c may provide such datasets, and/or the like to the predictive computing entity 102 which may leverage the datasets to generate predictive insights for variably sized cohorts within a population. In some examples, the datasets may include an aggregation of data from across the external computing entities 112a-c into one or more aggregated datasets. The external computing entities 112a-c, for example, may be associated with one or more data repositories, cloud platforms, compute nodes, organizations, and/or the like, which may be individually and/or collectively leveraged by the predictive computing entity 102 to obtain and aggregate data for a prediction domain.

The predictive computing entity 102 may include, or be in communication with, one or more processing elements 104 (also referred to as processors, processing circuitry, digital circuitry, and/or similar terms used herein interchangeably) that communicate with other elements within the predictive computing entity 102 via a bus, for example. As will be understood, the predictive computing entity 102 may be embodied in a number of different ways. The predictive computing entity 102 may be configured for a particular use or configured to execute instructions stored in volatile or non-volatile media or otherwise accessible to the processing element 104. As such, whether configured by hardware or computer program products, or by a combination thereof, the processing element 104 may be capable of performing steps or operations according to embodiments of the present disclosure when configured accordingly.

In one embodiment, the predictive computing entity 102 may further include, or be in communication with, one or more memory elements 106. The memory element 106 may be used to store at least portions of the databases, database instances, database management systems, data, applications, programs, program modules, scripts, source code, object code, byte code, compiled code, interpreted code, machine code, executable instructions, and/or the like being executed by, for example, the processing element 104. Thus, the databases, database instances, database management systems, data, applications, programs, program modules, scripts, source code, object code, byte code, compiled code, interpreted code, machine code, executable instructions, and/or the like, may be used to control certain aspects of the operation of the predictive computing entity 102 with the assistance of the processing element 104.

As indicated, in one embodiment, the predictive computing entity 102 may also include one or more communication interfaces 108 for communicating with various computing entities, e.g., external computing entities 112a-c, such as by communicating data, content, information, and/or similar terms used herein interchangeably that may be transmitted, received, operated on, processed, displayed, stored, and/or the like.

The computing system 100 may include one or more input/output (I/O) element(s) 114 for communicating with one or more users. An I/O element 114, for example, may include one or more user interfaces for providing and/or receiving information from one or more users of the computing system 100. The I/O element 114 may include one or more tactile interfaces (e.g., keypads, touch screens, etc.), one or more audio interfaces (e.g., microphones, speakers, etc.), visual interfaces (e.g., display devices, etc.), and/or the like. The I/O element 114 may be configured to receive user input through one or more of the user interfaces from a user of the computing system 100 and provide data to a user through the user interfaces.

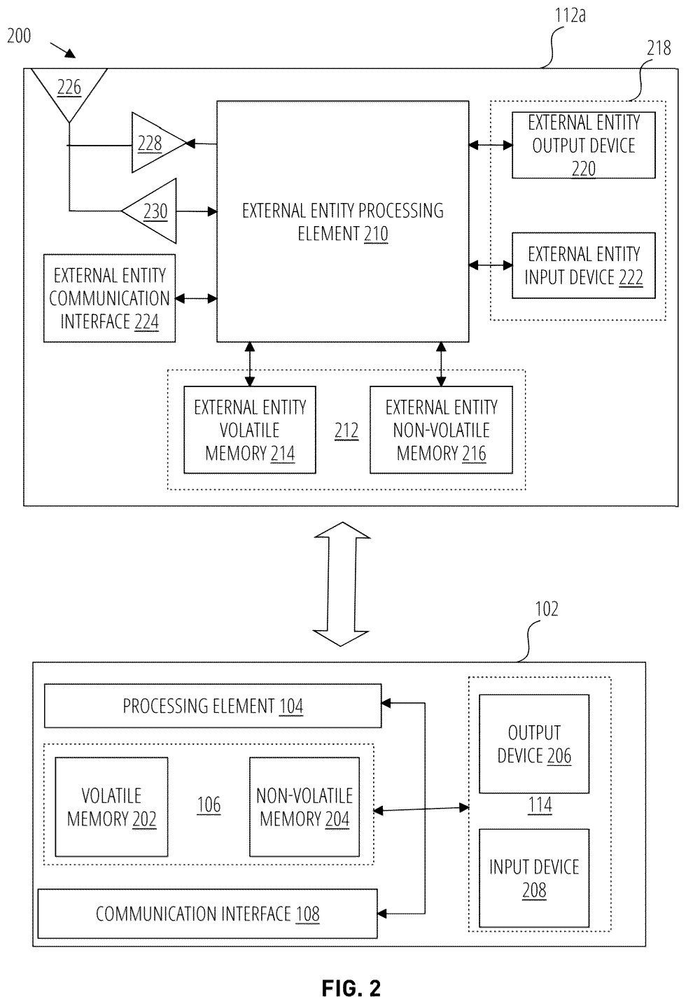

FIG. 2 is a schematic diagram showing a system computing architecture 200 in accordance with some embodiments discussed herein. In some embodiments, the system computing architecture 200 may include the predictive computing entity 102 and/or the external computing entity 112a of the computing system 100. The predictive computing entity 102 and/or the external computing entity 112a may include a computing apparatus, a computing device, and/or any form of computing entity configured to execute instructions stored on a computer-readable storage medium to perform certain steps or operations.

The predictive computing entity 102 may include a processing element 104, a memory element 106, a communication interface 108, and/or one or more I/O elements 114 that communicate within the predictive computing entity 102 via internal communication circuitry, such as a communication bus and/or the like.

The processing element 104 may be embodied as one or more complex programmable logic devices (CPLDs), microprocessors, multi-core processors, coprocessing entities, application-specific instruction-set processors (ASIPs), microcontrollers, and/or controllers. Further, the processing element 104 may be embodied as one or more other processing devices or circuitry including, for example, a processor, one or more processors, various processing devices, and/or the like. The term circuitry may refer to an entirely hardware embodiment or a combination of hardware and computer program products. Thus, the processing element 104 may be embodied as integrated circuits, application specific integrated circuits (ASICs), field programmable gate arrays (FPGAs), programmable logic arrays (PLAs), hardware accelerators, digital circuitry, and/or the like.

The memory element 106 may include volatile memory 202 and/or non-volatile memory 204. The memory element 106, for example, may include volatile memory 202 (also referred to as volatile storage media, memory storage, memory circuitry, and/or similar terms used herein interchangeably). In one embodiment, a volatile memory 202 may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for, or used in addition to, the computer-readable storage media described above.

The memory element 106 may include non-volatile memory 204 (also referred to as non-volatile storage, memory, memory storage, memory circuitry, and/or similar terms used herein interchangeably). In one embodiment, the non-volatile memory 204 may include one or more non-volatile storage or memory media, including, but not limited to, hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like.

In one embodiment, a non-volatile memory 204 may include a floppy disk, flexible disk, hard disk, solid-state storage (SSS) (e.g., a solid-state drive (SSD)), solid state card (SSC), solid state module (SSM), enterprise flash drive, magnetic tape, or any other non-transitory magnetic medium, and/or the like. A non-volatile memory 204 may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile memory 204 may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

As will be recognized, the non-volatile memory 204 may store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably may refer to a collection of records or data that is stored in a computer-readable storage medium using one or more database models, such as a hierarchical database model, network model, relational model, entity-relationship model, object model, document model, semantic model, graph model, and/or the like.

The memory element 106 may include a non-transitory computer-readable storage medium for implementing one or more aspects of the present disclosure including as a computer-implemented method configured to perform one or more steps/operations described herein. For example, the non-transitory computer-readable storage medium may include instructions that when executed by a computer (e.g., processing element 104), cause the computer to perform one or more steps/operations of the present disclosure. For instance, the memory element 106 may store instructions that, when executed by the processing element 104, configure the predictive computing entity 102 to perform one or more steps/operations described herein.

Embodiments of the present disclosure may be implemented in various ways, including as computer program products that comprise articles of manufacture. Such computer program products may include one or more software components including, for example, software objects, methods, data structures, or the like. A software component may be coded in any of a variety of programming languages. An illustrative programming language may be a lower-level programming language, such as an assembly language associated with a particular hardware framework and/or operating system platform. A software component comprising assembly language instructions may require conversion into executable machine code by an assembler prior to execution by the hardware framework and/or platform. Another example programming language may be a higher-level programming language that may be portable across multiple frameworks. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query, or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together, such as in a particular directory, folder, or library. Software components may be static (e.g., pre-established, or fixed) or dynamic (e.g., created or modified at the time of execution).

The predictive computing entity 102 may be embodied by a computer program product which includes non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media such as the volatile memory 202 and/or the non-volatile memory 204.

The predictive computing entity 102 may include one or more I/O elements 114. The I/O elements 114 may include one or more output devices 206 and/or one or more input devices 208 for providing and/or receiving information with a user, respectively. The output devices 206 may include one or more sensory output devices, such as one or more tactile output devices (e.g., vibration devices such as direct current motors, and/or the like), one or more visual output devices (e.g., liquid crystal displays, and/or the like), one or more audio output devices (e.g., speakers, and/or the like), and/or the like. The input devices 208 may include one or more sensory input devices, such as one or more tactile input devices (e.g., touch sensitive displays, push buttons, and/or the like), one or more audio input devices (e.g., microphones, and/or the like), and/or the like.

In addition, or alternatively, the predictive computing entity 102 may communicate, via a communication interface 108, with one or more external computing entities such as the external computing entity 112a. The communication interface 108 may be compatible with one or more wired and/or wireless communication protocols.

For example, such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. In addition, or alternatively, the predictive computing entity 102 may be configured to communicate via wireless external communication using any of a variety of protocols, such as general packet radio service (GPRS), Universal Mobile Telecommunications System (UMTS), Code Division Multiple Access 2000 (CDMA2000), CDMA2000 1X (1xRTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.9 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

The external computing entity 112a may include an external entity processing element 210, an external entity memory element 212, an external entity communication interface 224, and/or one or more external entity I/O elements 218 that communicate within the external computing entity 112a via internal communication circuitry, such as a communication bus and/or the like.

The external entity processing element 210 may include one or more processing devices, processors, and/or any other device, circuitry, and/or the like described with reference to the processing element 104. The external entity memory element 212 may include one or more memory devices, media, and/or the like described with reference to the memory element 106. The external entity memory element 212, for example, may include at least one external entity volatile memory 214 and/or external entity non-volatile memory 216. The external entity communication interface 224 may include one or more wired and/or wireless communication interfaces as described with reference to communication interface 108.

In some embodiments, the external entity communication interface 224 may be supported by one or more radio circuitry. For instance, the external computing entity 112a may include an antenna 226, a transmitter 228 (e.g., radio), and/or a receiver 230 (e.g., radio).

Signals provided to and received from the transmitter 228 and the receiver 230, correspondingly, may include signaling information/data in accordance with air interface standards of applicable wireless systems. In this regard, the external computing entity 112a may be capable of operating with one or more air interface standards, communication protocols, modulation types, and access types. More particularly, the external computing entity 112a may operate in accordance with any of a number of wireless communication standards and protocols, such as those described above with regard to the predictive computing entity 102.

Via these communication standards and protocols, the external computing entity 112a may communicate with various other entities using means such as Unstructured Supplementary Service Data (USSD), Short Message Service (SMS), Multimedia Messaging Service (MMS), Dual-Tone Multi-Frequency Signaling (DTMF), and/or Subscriber Identity Module Dialer (SIM dialer). The external computing entity 112a may also download changes, add-ons, and updates, for instance, to its firmware, software (e.g., including executable instructions, applications, program modules), operating system, and/or the like.

According to one embodiment, the external computing entity 112a may include location determining embodiments, devices, modules, functionalities, and/or the like. For example, the external computing entity 112a may include outdoor positioning embodiments, such as a location module adapted to acquire, for example, latitude, longitude, altitude, geocode, course, direction, heading, speed, universal time (UTC), date, and/or various other information/data. In one embodiment, the location module may acquire data, such as ephemeris data, by identifying the number of satellites in view and the relative positions of those satellites (e.g., using global positioning systems (GPS)). The satellites may be a variety of different satellites, including Low Earth Orbit (LEO) satellite systems, Department of Defense (DOD) satellite systems, the European Union Galileo positioning systems, the Chinese Compass navigation systems, Indian Regional Navigational satellite systems, and/or the like. This data may be collected using a variety of coordinate systems, such as the Decimal Degrees (DD); Degrees, Minutes, Seconds (DMS); Universal Transverse Mercator (UTM); Universal Polar Stereographic (UPS) coordinate systems; and/or the like. Alternatively, the location information/data may be determined by triangulating a position of the external computing entity 112a in connection with a variety of other systems, including cellular towers, Wi-Fi access points, and/or the like. Similarly, the external computing entity 112a may include indoor positioning embodiments, such as a location module adapted to acquire, for example, latitude, longitude, altitude, geocode, course, direction, heading, speed, time, date, and/or various other information/data. Some of the indoor systems may use various position or location technologies including RFID tags, indoor beacons or transmitters, Wi-Fi access points, cellular towers, nearby computing devices (e.g., smartphones, laptops), and/or the like. For instance, such technologies may include the iBeacons, Gimbal proximity beacons, Bluetooth Low Energy (BLE) transmitters, NFC transmitters, and/or the like. These indoor positioning embodiments may be used in a variety of settings to determine the location of someone or something with inches or centimeters.

The external entity I/O elements 218 may include one or more external entity output devices 220 and/or one or more external entity input devices 222 that may include one or more sensory devices described herein with reference to the I/O elements 114. In some embodiments, the external entity I/O element 218 may include a user interface (e.g., a display, speaker, and/or the like) and/or a user input interface (e.g., keypad, touch screen, microphone, and/or the like) that may be coupled to the external entity processing element 210.

For example, the user interface may be a user application, browser, and/or similar words used herein interchangeably executing on and/or accessible via the external computing entity 112a to interact with and/or cause the display, announcement, and/or the like of information/data to a user. The user input interface may include any of a number of input devices or interfaces allowing the external computing entity 112a to receive data including, as examples, a keypad (hard or soft), a touch display, voice/speech interfaces, motion interfaces, and/or any other input device. In embodiments including a keypad, the keypad may include (or cause display of) the conventional numeric (0-9) and related keys (#, *, and/or the like), and other keys used for operating the external computing entity 112a and may include a full set of alphabetic keys or set of keys that may be activated to provide a full set of alphanumeric keys. In addition to providing input, the user input interface may be used, for example, to activate or deactivate certain functions, such as screen savers, sleep modes, and/or the like.

### III. Examples of Certain Terms

In some embodiments, the term “entity cohort” to refers to a data entity that describes a subset of entities within a prediction domain. An entity may be any person, animal, object, and/or the like that is associated with a particular prediction domain. An entity cohort may include a subset of a plurality of entities within the particular prediction domain that are grouped based on one or more cohort criteria. By way of example, an entity cohort may include a subset of entities that share one or more common and/or related attributes that are defined by one or more cohort criteria, such as one or more entities that are located within a geographic region, share one or more demographic characteristics, are members of a common membership plan, and/or the like. The one or more common and/or related attributes, for example, may be defined by the one or more cohort criteria. In some examples, one or more cohort criteria may be identified by one or more selection inputs. In some examples, an entity cohort may be generated in response to the one or more selection inputs.

An entity cohort may depend on a prediction domain. As one example, in a clinical domain, an entity cohort may include a subset of members of healthcare system that are located within a particular geographic region. In some examples, the particular geographic region may be identified through a selection input, for example, to a geographic interface and/or the like.

In some embodiments, the term “selection input” refers to data input to a computing system. A selection input, for example, may include user input provided through a user interface. A selection input may identify one or more parameters for defining and/or generating one or more predictions for an entity cohort. For example, a selection input may include one or more criteria for an entity cohort, such as a selection of a particular geographic region, and/or the like. In some examples, the one or more criteria may be dynamically selected through one or more user interactions (e.g., dragging, zooming, expanding, etc.) with a geographic representation provided by a user interface. By way of example, a user may zoom into and/or out of one or more geographic regions to generate entity cohorts of different sizes.

In addition, or alternatively, a selection input may identify one or more target predictions for an entity cohort. The one or more target predictions, for example, may include one or more simulated error outcomes corresponding to one or more selected error correction actions, and/or the like.

In some embodiments, the term “user interface” refers to one or more communication mechanisms between a user and a computing system. A user interface, for example, may include one or more visual displays, tactile input mechanisms (e.g., touch screens, keyboards, etc.), audio input mechanisms, and/or the like. In some examples, a user interface may be configured to receive a selection input and, in response to the selection input, generate and provide one or more prediction-based outputs.

By way of example, a user interface may include an embedded simulation engine and/or be communicatively connected to one or more network devices that are collectively and/or individually configured to perform one or more operations of the present disclosure to establish an entity cohort and/or generate one or more predictive insights for the entity cohort. In this way, a user interface may be enabled to track predicted documentation errors between documented parameter rates and/or predicted parameter rates across different entity cohorts, as described herein. A user interface may allow selections to be made to alter predictive outcomes to facilitate the determination of optimal error correction actions. By way of example, a user interface may provide simulation data for display to allow better comprehension of the impacts of various error correction actions on an entity cohort. In this manner, a user interface may surface interactive entity cohort specific information with which a user may interact (e.g., by zooming in/out, etc.) to detect and address predictive insights for different entity cohorts. Moreover, a user interface may allow a user to simulate the performance of different error correction actions to visualize improvements for an entity cohort using causal modeling, as described herein.

In some embodiments, the term “entity data object” refers to a data entity that describes an entity within a prediction domain. An entity data object, for example, may include a plurality of entity attributes for an entity.

In some embodiments, the term “entity attribute” refers to a data parameter that describes a characteristic of an entity within a prediction domain. An entity attribute, for example, may include a current attribute that is descriptive of one or more current characteristics of an entity, such as one or more demographic characteristics, location characteristics, and/or the like. In addition, or alternatively, an entity attribute may include a historical attribute that is descriptive of one or more historical characteristics of an entity, such as one or more recorded events, and/or the like.

An entity attribute may depend on a prediction domain. As one example, in a clinical domain, entity attributes may include one or more current attributes, such as current (e.g., within a current year) medical diagnoses, residential location, one or more demographic classes, and/or the like. In addition, or alternatively, in a clinical domain, entity attributes may include one or more historical attributes, such as historical (e.g., preceding a current year) medical diagnoses, clinical encounters (e.g., hospital visits, etc.), and/or the like.

In some embodiments, the term “documented parameter rate” refers to data value that describes a rate at which a parameter of interest is recorded within an entity cohort. A documented parameter rate, for example, may include a percentage, ratio, and/or the like of an entity cohort that has been documented with a parameter of interest within a time interval, such as a month, year, and/or the like. By way of example, a documented parameter rate may correspond to a time interval of interest. In some examples, the time interval of interest may include a plurality of time increments (e.g., months within a year, etc.). In some examples, a documented parameter rate may be generated for a time interval (e.g., a year) and then allocated to a plurality of time increments (e.g., months, etc.) to forecast a glide path at a time increment level.

A documented parameter rate may depend on a parameter of interest and/or prediction domain. As one example, in a clinical domain, a parameter of interest may include a disease and/or category of diseases, such as one or more diseases characterized by a hierarchical condition category (HCC) code. In such a case, a documented parameter rate may include a ratio of entities (e.g., members of a healthcare system) that have been diagnosed with the HCC code within a time interval (and/or time increment thereof). By way of example, the documented parameter rate may be derived from claims data for an entity cohort that describes a plurality of medical claims issued for each of the entities within the entity cohort during the time interval.

In some embodiments, the term “predicted parameter rate” refers to data value that describes a predicted rate at which a parameter of interest is present within an entity cohort. A predicted parameter rate, for example, may include a percentage, ratio, and/or the like of an entity cohort that is predicted to be associated with a parameter of interest within a time interval, such as a month, year, and/or the like. By way of example, a predicted parameter rate may correspond to a time interval of interest. In some examples, the time interval of interest may include a plurality of time increments (e.g., months within a year, etc.). In some examples, a predicted parameter rate may be generated for a time interval (e.g., a year) and then allocated to a plurality of time increments (e.g., months, etc.) to forecast a glide path at a time increment level.

A predicted parameter rate may depend on a parameter of interest and/or prediction domain. As one example, in a clinical domain, a parameter of interest may include a disease and/or category of diseases, such as one or more diseases characterized by an HCC code. In such a case, a predicted parameter rate may include a ratio of entities (e.g., members of a healthcare system) that are expected to be diagnosed with the HCC code within a time interval (and/or time increment thereof). By way of example, the predicted parameter rate may be derived from the documented parameter rate, one or more historical attributes for the entity cohort, one or more predictive models, and/or the like.

In some embodiments, a predicted parameter rate is generated based on a plurality of entity-specific parameter scores for each entity of an entity cohort. For instance, a predicted parameter rate may be aggregated from a plurality of individual entity-specific parameter scores. In this manner, a predicted parameter rate may be stratified into a plurality of different population metrics for different population sizes in an interactive manner.

In some embodiments, the term “entity-specific parameter score” refers to a data value that describes an individual entity's likelihood of having a parameter of interest. For example, an entity-specific parameter score may include a real number, probability value, percentage, and/or the like that describes an entity-level (e.g., member-level for a clinical domain) probability of being associated with a parameter of interest. For example, an entity-specific parameter score may include a value within a defined range, such as zero to one, in which a first value (e.g., 0) of the defined range indicates a low likelihood of being associated with a parameter of interest and a high value (e.g., 1) indicates a high likelihood of being associated with the parameter of interest. In some examples, an entity-specific parameter score may include a high value (e.g., 1 in a defined range of 0 to 1) in the event that an entity is associated with a currently documented parameter of interest. In some examples, an entity-specific parameter score may include a value within the defined range in the event that an entity is not associated with a currently documented parameter of interest. By way of example, an entity-specific parameter score for an entity that is not associated with a currently documented parameter of interest may include a parameter risk score for the entity.

In some embodiments, an entity-specific parameter score includes at least one of a parameter recapture score, parameter risk score, and/or combination thereof. For example, an entity-specific parameter score a may include a transformation of a parameter risk score to a parameter recapture score for an entity of the entity cohort.

In some embodiments, the term “parameter recapture score” refers to an entity-specific parameter score that is predicted based on historical records for a parameter of interest. For example, a parameter recapture score may be configured to measure a likelihood of a parameter of interest based on one or more chronic and/or acute parameter instances previously recorded for an individual entity. In some examples, a parameter recapture score may be generated for each entity of an entity cohort that is associated with at least one previously recorded chronic and/or acute parameter instance.

In some embodiments, a parameter recapture score is generated, using one or more rule-based techniques, based on historical attributes associated with an entity. For instance, a parameter recapture score may be based on a set of rule-based recapture factors. The set of rule-based recapture factors, for example, may determine whether a historically recorded parameter of interest for an entity is a chronic parameter or an acute parameter with respect to the entity. In a clinical domain, for example, a life-long chronic disease (e.g., characterized by an HCC code) may converge towards a high parameter recapture score (e.g., 1) and acute conditions may converge towards lower parameter recapture score (e.g., 0).

By way of example, in a clinical domain, at the beginning of a time interval (e.g., a program year), a parameter recapture score may be determined across one or more entities of the entity cohort for a parameter of interest, such as a set of diseases characterized by an HCC code. There is a complexity here in the fact that a parameter of interest may manifest as chronic life long lasting conditions, acute conditions, or some that may phase out over a time frame longer than a time interval. To accommodate for these manifestations, each instance of a parameter of interest in analyzed over time to determine whether the instance is evidence of a chronic condition (e.g., a condition diagnosed in at least two consecutive time intervals, etc.) or an acute condition (e.g., a condition that is not diagnosed in at least two consecutive time intervals). The chronic and acute condition prediction may be refined based on one or more contextual recapture attributes that accommodate for factors that may vary by market, geolocation, and/or the like.

In some embodiments, in response to a chronic condition for a parameter of interest, a high parameter recapture score (e.g., a 1) is assigned to an entity. In response to an acute condition for a parameter of interest, a neutral parameter recapture score (e.g., between 0 and 1) may be assigned to an entity based one or more entity attributes, contextual recapture attributes, and/or the like.

In some embodiments, the term “parameter risk score” refers to an entity-specific parameter score that is predicted in the absence of historical records for a parameter of interest. For example, a parameter risk score may include an imputed probability score (e.g., an imputed disease probability score for a clinical domain, etc.). A parameter risk score, for example, may be configured to measure a likelihood of a parameter of interest based on one or more entity attributes of an individual entity (e.g., as recorded by an entity data object, etc.). In some examples, a parameter risk score may be generated for each entity of an entity cohort that is not associated with a parameter recapture score.

In some embodiments, a parameter risk score is generated, using one or more machine learning-based techniques, based on entity attributes associated with an entity. For example, a parameter risk score may include a projection of a new and unique risk that is may emerge for an individual entity (and/or a healthcare program when combined across a plurality of entities). In some examples, the parameter risk score may be generated using time series prediction techniques that generate a risk score based on entity attributes (e.g., clinical and/or non-clinical information about the members in a clinical domain) to predict emerging risk for a parameter of interest (e.g., each of one or more HCCs in a clinical domain).

By way of example, in a clinical domain, a parameter risk score is generated if a condition has never been present (or documented) for an entity. To do so, one or more machine learning prediction models may probabilistically identify a likelihood of a condition being present and/or a likelihood of a condition being documented in a future time interval. The machine learning models, for example, may include one or more pretrained international classification of diseases (ICD) code and/or HCC probabilistic modeling frameworks that may be previously trained to generate parameter risk scores based on entity attributes of an entity data object. Each parameter risk score may identify a probability that an entity (e.g., a member of a healthcare system) will be diagnosed with a parameter of interest within a time interval (e.g., program year, etc.).

In some embodiments, the term “machine learning prediction model” refers to a data entity that describes parameters, hyper-parameters, and/or defined operations of a rules-based and/or machine learning model (e.g., model including at least one of one or more rule-based layers, one or more layers that depend on trained parameters, coefficients, and/or the like). A machine learning prediction model may include one or more machine learning models configured, trained (e.g., jointly, separately, etc.), and/or the like to generate parameter risk scores for one or more entities within an entity cohort. A machine learning prediction model may include one or more of any type of machine learning model including one or more supervised, unsupervised, semi-supervised, reinforcement learning models, and/or the like. In some examples, a machine learning prediction model may include multiple models configured to perform one or more different stages of a prediction process.

In some embodiments, a machine learning prediction model is trained using time-series data. By way of example, a machine learning prediction model may include a bi-directional long short-term memory (LSTM) model with one or more attention layers. The bi-directional LSTM may be trained to generate one or more time-series embeddings from the time-series data for prediction modeling. One or more supervised prediction models (e.g., support vector machines, neural networks, random forests, etc.) may be trained, using one or more supervised training techniques (e.g., back propagation of errors, etc.) to generate parameter risk scores based on the time-series embeddings and/or a labelled training dataset.

In some embodiments, the term “projected parameter rate” refers to a predicted parameter rate that is augmented to provide one or more rate visualizations. For instance, a predicted parameter rate may be leveraged to generate a projected parameter rate that projects to one or more future time intervals and/or time increments thereof. In this manner, a predicted parameter rate may enable forecasting of one or more predictive insights (e.g., disease burden in a clinical domain, etc.) to a future time interval and/or one or more time increments of a current and/or future time interval.

By way of example, a predicted parameter rate may be broken up into a plurality of time increments (e.g., monthly subcomponents of a year, etc.) that aggregate to the high-level estimate for the entire time interval. This data may then allow for better glide path projection and allow for enhanced granularity in terms of specific cohort projections.

In some embodiments, the term “predicted documentation error” refers to a data value that describes a predicted under representation of a parameter of interest within an entity cohort. For instance, a predicted documentation error may be based on one or more differences between a documented parameter rate and a predicted parameter rate for an entity cohort. A predicted documentation error, for example, may be based on a comparison between a documented parameter rate and a predicted parameter rate for an entity cohort. By way of example, a predicted documentation error may include a distance between a documented parameter rate and a predicted parameter rate for an entity cohort.

In some embodiments, the term “error threshold” refers to a data value that describes documentation criteria for an entity cohort. An error threshold, for example, may be a real number, percentage, probability, and/or the like that describes an acceptable predicted documentation error. By way of example, an error threshold may include a percentage threshold, such as a 3%, 5%, 10%, and/or the like, which describes an acceptable ratio of under documented parameters of interest within an entity cohort. In some examples, an error threshold may be cohort specific. For instance, an error threshold may be a function of a geographic region, one or more region attributes (e.g., rural/urban, healthcare accessibility, etc.), one or more entity attributes (e.g., average demographics such as age, etc.), one or more cohort attributes (e.g., a number of entities within an entity cohort, etc.), and/or the like. In addition, or alternatively, an error threshold may be cohort generic. For instance, a static error threshold may be applied to each of a plurality of different entity cohorts.

In some embodiments, the term “error correction action” refers to a prediction-based action that may be selected to decrease a predicted documentation error for an entity cohort. For example, an error correction action may be selected from a plurality of potential error correction actions for an entity cohort. In some examples, an error correction action may be selected in response to a predicted documentation error exceeding an error threshold. In some examples, an error correction action may be selected based on selection input. An error correction action, for example, may include an optimal clinical measure for an entity cohort within a clinical domain.

In some embodiments, the term “potential error correction action” refers to one of one or more potential prediction-based actions for an entity cohort. For example, one or more potential error correction actions may include one or more processes, programs, actions, and/or sequences thereof that may be implemented for an entity cohort to improve a documented parameter rate. A potential error correction action may depend on a prediction domain. As some examples, in a clinical domain, a potential error correction action may include one or more house call programs to improve house call penetration, primary care provider (PCP) engagement incentive programs, clinical interventions, healthcare campaigns, and/or the like.

In some embodiments, the term “cohort-specific causal model” refers to a data construct that describes one or more causal relationships within one or more entity cohorts. For example, a cohort-specific causal model may refer to, or include, parameters, hyperparameters, and/or defined operations of a causal model that is configured to generate one or more nonlinear causal impact predictions of one or more causal variables on a predictive outcome associated with entities of one or more entity cohorts. One or more causal variables, for example, may include entity attributes associated with one or entity data objects corresponding to an entity cohort. In some examples, nonlinear causal impact predictions may be based on historical data and/or one or more knowledge graphs associated with a prediction domain. A cohort-specific causal model, for example, may include a directed acyclic graph (DAG) that defines one or more causal relationships between the one or more entity attributes and a predictive outcome. A predictive outcome, for example, may include a prediction that an entity will be documented with a parameter of interest (e.g., thereby improving a documented parameter rate of an entity cohort) in response to a potential error correction action.

In some embodiments, a cohort-specific causal model is an intervention predictive model that enables an understanding of a potential impact of a potential error correction action on a documented parameter rate of an entity cohort. In some examples, a cohort-specific causal model may provide a cause/effect multi-input/single-output capability that may be overlayed (e.g., within a user interface, etc.) to documentation insights for an entity cohort to statistically evaluate various potential error correction actions for an entity cohort. By way of example, a cohort-specific causal model may include a multi-variate model that broadly assesses how potential error correction actions with regards programs or campaigns within an entity cohort may impact predicted documentation errors.

In some embodiments, a cohort-specific causal model is configured to output an entity-specific impact prediction for each entity within an entity cohort. Each entity-specific impact prediction may describe a likelihood that a respective entity of an entity cohort will be documented with a parameter of interest in response to a potential error correction action. In some examples, a simulated error correction outcome may be generated by aggregating an entity-specific impact prediction for one or more entities within an entity cohort. In addition, or alternatively, a cohort-specific causal model may be configured to output the simulated error correction outcome.

In some embodiments, the term “simulated error correction outcome” refers to a data value that describe an expected increase in a documented parameter rate for an entity cohort in response to an error correction action. A simulated error correction outcome, for example, may be a real number, percentage, probability, and/or the like that describes an estimated change in a document parameter rate. By way of example, a simulated error correction outcome may include a percentage increase, such as a 3%, 5%, 10%, and/or the like, which describes a simulated outcome of an implementation of an error correction action with respect to an entity cohort.

### IV. Overview

Embodiments of the present disclosure present prediction and activity forecasting techniques that leverage entity-level predictions to improve traditional population forecasting and tracking technologies. Some techniques of the present disclosure generate entity-level predictions through a multi-stage process that combines historical data with entity-level parameter forecasting techniques to generate predictions that are grounded by historical data and refined, expanded, and extrapolated by predictive modeling. By doing so, the forecasting techniques of the present disclosure enable more accurate and comprehensive entity-level predictions at the expense of less computing resources. In this manner, some of the techniques of the present disclosure provide technical improvements to traditional computer-based forecasting technologies that improve the allocation of computing resources while enabling predictions of increased accuracy that comprehensively cover a population. These improved forecasting techniques may be practically applied in a number of different prediction domains, such as a clinical domain in which some of the techniques of the present disclosure may enable accurate and comprehensive patient-level predictions for predicting illness burdens in populations of various sizes, demographics, and/or the like.

Using some of the techniques of the present disclosure, entity-level predictions, such as entity-specific parameter scores, may be aggregated to generate cohort-level predictions, such as predictive parameter rates, for variably sized cohorts within a population. This, in turn, enables the real time generation of dynamic predictive parameter rates that are tailored to interactive cohorts defined by a range of different cohort criteria. In this way, some of the techniques of the present disclosure, enable enhanced projections of the parameter rates, such as member illness burdens in a clinical domain, at more granular levels than traditional techniques. This allows for increased accuracy for tracking documented parameter rates (e.g., actual risk adjustment factor, etc.) versus expected parameter rates (e.g., actual risk adjustment factor, etc.) and enables the initiation, evaluation, and forecasting of prediction-based actions (e.g., program/process adjustments, etc.) in real time through an enhanced user interface. For example, some of the techniques of the present disclosure may provide integrated analytics that allow users to generate interactive predictions on the fly and generate predictive insights dynamically for evaluating a population at various levels of granularity. In this way, some of the techniques of the present disclosure enable improved user interfaces, among other underlying prediction mechanisms, which may dynamically demonstrate the impacts of multiple scenarios, such as increasing/decreasing penetration rates, prevalence, recapture, and never previously diagnosed parameters, and/or the like, on a population.

Examples of technologically advantageous embodiments of the present disclosure include: (i) entity-level prediction techniques for generating interactive predictive parameter rates, (ii) simulation techniques for evaluating predictive actions with respect to interactive cohorts, (iii) visualization techniques for overlaying, visualizing, and interacting with entity-, cohort-, and/or population-level insights, among others. Other technical improvements and advantages may be realized by one of ordinary skill in the art.

### V. Example System Operations

As indicated, various embodiments of the present disclosure make important technical contributions to population forecasting and tracking technologies, as well as user interface, visualization, and simulation technologies. In particular, systems and methods are disclosed herein that leverage entity-level predictions to generate improved predictive insights for a population. Unlike traditional techniques, some of the techniques of the present disclosure build cohort level predictions from individual entity-level insights to enable the generation, presentation, and evaluation of predictive insights, on the fly, for variably defined entity cohorts.

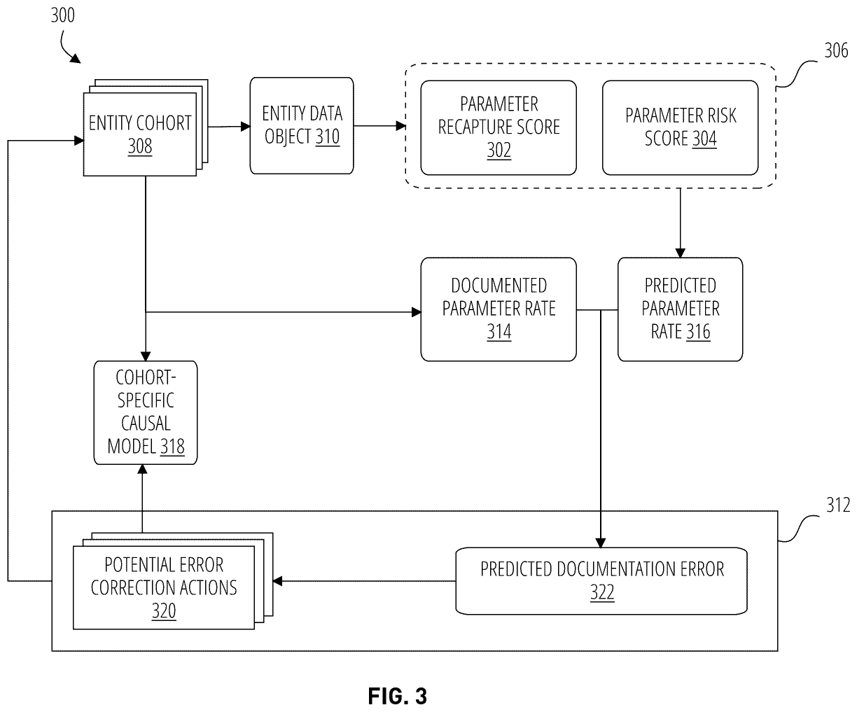

FIG. 3 is a dataflow diagram 300 showing example data structures and modules for generating predictive insights for an entity cohort in accordance with some embodiments discussed herein. The dataflow diagram 300, for example, illustrates a user interface 312 that may be configured to receive selection inputs for an entity cohort 308 and potential error correction actions 320 based on predictive insights, such as predicted documentation errors 322, for the entity cohort 308. The entity cohort 308 may be processed, using one or more techniques of the present disclosure, to determine interactive predictive insights that seamlessly adapt to a particular entity cohort 308. In this way, real world insights may be generated, evaluated, and compared across distinct entity cohorts to enable the identification of cohorts of interest and effective prediction-based actions that are optimized for cohorts of interest in real time.

In some embodiments, the entity cohort 308 is selected based on a selection input to the user interface 312. In some examples, the predicted documentation error 322 is generated in response to the selection input.

In some embodiments, the selection input is a data input to a computing system and/or portion thereof, such as the user interface 312. The selection input, for example, may include user input provided through the user interface 312. The selection input may identify one or more parameters for defining and/or generating one or more predictions for the entity cohort 308. For example, the selection input may include one or more criteria for the entity cohort 308, such as a selection of a particular geographic region, and/or the like. In some examples, the one or more criteria may be dynamically selected through one or more user interactions (e.g., dragging, zooming, expanding, etc.) with a geographic visualization provided by the user interface 312. By way of example, a user may zoom into and/or out of one or more geographic regions to generate entity cohorts 308 of various sizes.

In addition, or alternatively, a selection input may identify one or more target predictions for the entity cohort 308. The one or more target predictions, for example, may include one or more simulated error outcomes corresponding to one or more selected error correction actions, and/or the like.

In some embodiments, the user interface 312 is one or more communication mechanisms between a user and a computing system. The user interface 312, for example, may include one or more visual displays, tactile input mechanisms (e.g., touch screens, keyboards, etc.), audio input mechanisms (e.g., microphones, etc.), and/or the like. In some examples, the user interface 312 may be configured to receive a selection input and, in response to the selection input, generate and provide one or more prediction-based outputs.

By way of example, the user interface 312 may include an embedded simulation engine and/or be communicatively connected to one or more network devices that are collectively and/or individually configured to perform one or more operations of the present disclosure to establish the entity cohort 308 and/or generate one or more predictive insights for the entity cohort 308. In this way, the user interface 312 may be enabled to track predicted documentation errors 322 between documented parameter rates 314 and/or predicted parameter rates 316 across different entity cohorts 308, as described herein. The user interface 312 may allow selections to be made to alter predictive outcomes to facilitate the determination of optimal error correction actions. By way of example, the user interface 312 may provide simulation data for display to allow better comprehension of the impacts of various potential error correction actions 320 on an entity cohort 308. In this manner, the user interface 312 may surface interactive entity cohort specific information with which a user may interact (e.g., by zooming in/out, etc.) to detect and address predictive insights for different entity cohorts 308. Moreover, the user interface 312 may allow a user to simulate the performance of different potential error correction actions 320 to visualize improvements for the entity cohort 308 using causal modeling, as described herein.

In some embodiments, the entity cohort 308 is a data entity that describes a subset of entities within a prediction domain. An entity may be any person, animal, object, and/or the like that is associated with a particular prediction domain. The entity cohort 308 may include a subset of a plurality of entities within the particular prediction domain that are grouped based on one or more cohort criteria. By way of example, the entity cohort 308 may include a subset of entities that share one or more common and/or related attributes that are defined by one or more cohort criteria, such as one or more entities that are located within a geographic region, share one or more demographic characteristics, are members of a common membership plan, and/or the like. The one or more common and/or related attributes, for example, may be defined by the one or more cohort criteria. In some examples, one or more cohort criteria may be identified by one or more selection inputs to the user interface 312. In some examples, the entity cohort 308 may be generated in response to the one or more selection inputs.

The entity cohort 308 may depend on a prediction domain. As one example, in a clinical domain, the entity cohort 308 may include a subset of members of healthcare system that are located within a particular geographic region. In some examples, the particular geographic region may be identified through a selection input, for example, to a geographic interface and/or the like.

In some embodiments, the entity data object 310 is a data entity that describes an entity within a prediction domain. The entity data object 310, for example, may include a plurality of entity attributes for an entity.

In some embodiments, an entity attribute is a data parameter that describes a characteristic of an entity within a prediction domain. An entity attribute, for example, may include a current attribute that is descriptive of one or more current characteristics of an entity, such as one or more demographic characteristics, location characteristics, and/or the like. In addition, or alternatively, an entity attribute may include a historical attribute that is descriptive of one or more historical characteristics of an entity, such as one or more recorded events, and/or the like.

An entity attribute may depend on a prediction domain. As one example, in a clinical domain, entity attributes may include one or more current attributes, such as current (e.g., within a current year) medical diagnoses, residential location, one or more demographic classes, and/or the like. In addition, or alternatively, in a clinical domain, entity attributes may include one or more historical attributes, such as historical (e.g., preceding a current year) medical diagnoses, clinical encounters (e.g., hospital visits, etc.), and/or the like.

In some embodiments, a documented parameter rate 314 is generated for the entity cohort 308.

In some embodiments, the documented parameter rate 314 refers to data value that describes a rate at which a parameter of interest is recorded within the entity cohort 308. A documented parameter rate 314, for example, may include a percentage, ratio, and/or the like of the entity cohort 308 that has been documented with a parameter of interest within a time interval, such as a month, year, and/or the like. By way of example, a documented parameter rate 314 may correspond to a time interval of interest. In some examples, the time interval of interest may include a plurality of time increments (e.g., months within a year, etc.). In some examples, a documented parameter rate 314 may be generated for a time interval (e.g., a year) and then allocated to a plurality of time increments (e.g., months, etc.) to forecast a glide path at a time increment level. In addition, or alternatively, the documented parameter rate 314 may be generated for a time increment forecasted for the entire time interval.

The documented parameter rate 314 may depend on a parameter of interest and/or prediction domain. As one example, in a clinical domain, a parameter of interest may include a disease and/or category of diseases, such as one or more diseases characterized by an HCC code. In such a case, the documented parameter rate 314 may include a ratio of entities (e.g., members of a healthcare system, etc.) that have been diagnosed with the HCC code within a time interval (and/or time increment thereof). By way of example, the documented parameter rate 314 may be derived from claims data for the entity cohort 308 that describes a plurality of medical claims issued for each of the entities within the entity cohort 308 during the time interval.

In some embodiments, a plurality of entity-specific parameter scores 306 are generated for the entity cohort 308. In some examples, the plurality of entity-specific parameter scores 306 includes a respective parameter risk score 304 for one or more of a plurality of entity data objects 310 within the entity cohort 308. The parameter risk score 304 may include a value between zero and one. In some examples, the entity-specific parameter score 306 may be generated using a machine learning prediction model. The machine learning prediction model, for example, may be previously trained to generate a parameter risk score 304 based on one or more entity attributes. The respective parameter risk score 304, for example, may be based on one or more respective entity attributes of a respective entity data object 310 within the entity cohort 308. In addition, or alternatively, the plurality of entity-specific parameter scores 306 includes a respective parameter recapture score 302 for one or more of the plurality of entity data objects 310.

In some embodiments, the entity-specific parameter score 306 is a data value that describes an individual entity's likelihood of having a parameter of interest. For example, the entity-specific parameter score 306 may include a real number, probability value, percentage, and/or the like that describes an entity-level (e.g., member-level for a clinical domain) probability of being associated with a parameter of interest. For example, the entity-specific parameter score may include a value within a defined range, such as zero to one, in which a first value (e.g., 0) of the defined range indicates a low likelihood of being associated with a parameter of interest and a high value (e.g., 1) indicates a high likelihood of being associated with the parameter of interest. In some examples, the entity-specific parameter score 306 may include a high value (e.g., 1 in a defined range of 0 to 1) in the event that an entity is associated with a currently documented parameter of interest. In some examples, the entity-specific parameter score 306 may include a value within the defined range (e.g., between 0 and 1) in the event that the entity is not associated with a currently documented parameter of interest. By way of example, the entity-specific parameter score 306 for an entity that is not associated with a currently documented parameter of interest may include a parameter risk score 304 for the entity.

In some embodiments, the entity-specific parameter score 306 includes at least one of a parameter recapture score 302, parameter risk score 304, and/or combination thereof. For example, the entity-specific parameter score 306 may include a transformation of the parameter risk score 304 to the parameter recapture score 302 for a entity of the entity cohort 308.

In some embodiments, the parameter recapture score 302 is an entity-specific parameter score 306 that is predicted based on historical records for a parameter of interest. For example, a parameter recapture score 302 may be configured to measure a likelihood of a parameter of interest based on one or more chronic and/or acute parameter instances previously recorded for an individual entity. In some examples, the parameter recapture score 302 may be generated for each entity of the entity cohort 308 that is associated with at least one previously recorded chronic and/or acute parameter instance.

In some embodiments, the parameter recapture score 302 is generated, using one or more rule-based techniques, based on historical attributes associated with an entity (e.g., as recorded by the respective entity data object 310, claims data in a clinical domain, etc.). For instance, the parameter recapture score 302 may be based on a set of rule-based recapture factors. The set of rule-based recapture factors, for example, may determine whether a historically recorded parameter of interest for an entity is a chronic parameter and/or an acute parameter with respect to the entity. In a clinical domain, for example, a life-long chronic disease (e.g., characterized by an HCC code) may converge towards a high parameter recapture score and acute conditions may converge towards lower parameter recapture score.

By way of example, in a clinical domain, at the beginning of a time interval (e.g., a program year), a parameter recapture score 302 may be determined across one or more entities of the entity cohort 308 for a parameter of interest, such as a set of diseases characterized by an HCC code. There is a complexity here in the fact that a parameter of interest may manifest as chronic life long lasting conditions, acute conditions, or some that may phase out over a time frame longer than a time interval. To accommodate for these manifestations, each instance of a parameter of interest in analyzed over time to determine whether the instance is evidence of a chronic condition (e.g., a condition diagnosed in at least two consecutive time intervals, etc.) or an acute condition (e.g., a condition that is not diagnosed in at least two consecutive time intervals). The chronic and acute condition prediction may be refined based on one or more contextual recapture attributes that accommodate for factors that may vary by market, geolocation, and/or the like.

In some embodiments, in response to a chronic condition for a parameter of interest, a high parameter recapture score (e.g., a 1) is assigned to an entity. In response to an acute condition for a parameter of interest, a neutral parameter recapture score (e.g., between 0 and 1) may be assigned to an entity based one or more entity attributes, contextual recapture attributes, and/or the like.

In some embodiments, a parameter risk score 304 is an entity-specific parameter score 306 that is predicted in the absence of (and/or to augment) historical records for a parameter of interest. For example, the parameter risk score 304 may include an imputed probability score (e.g., an imputed disease probability score for a clinical domain, etc.). The parameter risk score 304, for example, may be configured to measure a likelihood of a parameter of interest based on one or more entity attributes of an individual entity (e.g., as recorded by an entity data object 310, etc.). In some examples, the parameter risk score 304 may be generated for each entity of the entity cohort 308 that is not associated with a parameter recapture score 302.

In some embodiments, the parameter risk score 304 is generated, using one or more machine learning-based techniques, based on entity attributes associated with an entity. For example, the parameter risk score 304 may include a projection of a new and unique risk that may emerge for an individual entity (and/or a healthcare program when combined across a plurality of entities). In some examples, the parameter risk score 304 may be generated using time series prediction techniques that generate a risk score based on entity attributes (e.g., clinical and/or non-clinical information about the members in a clinical domain) to predict emerging risk for a parameter of interest (e.g., each of one or more HCCs in a clinical domain).

By way of example, in a clinical domain, the parameter risk score 304 is generated if a condition has never been present (or documented) for an entity. To do so, one or more machine learning prediction models may probabilistically identify a likelihood of a condition being present and/or a likelihood of a condition being documented in a future time interval. The machine learning models, for example, may include one or more pretrained international classification of diseases (ICD) code and/or HCC probabilistic modeling frameworks that may be previously trained to generate parameter risk scores 304 based on entity attributes of an entity data object 310. Each parameter risk score 304 may identify a probability that an entity (e.g., a member of a healthcare system) will be diagnosed with a parameter of interest within a time interval (e.g., program year, etc.).

In some embodiments, the machine learning prediction models are data entities that describe parameters, hyper-parameters, and/or defined operations of a rules-based and/or machine learning model (e.g., model including at least one of one or more rule-based layers, one or more layers that depend on trained parameters, coefficients, and/or the like). The machine learning prediction models may include one or more machine learning models configured, trained (e.g., jointly, separately, etc.), and/or the like to generate parameter risk scores 304 for one or more entities within the entity cohort 308. The machine learning prediction model may include one or more of any type of machine learning model including one or more supervised, unsupervised, semi-supervised, reinforcement learning models, and/or the like. In some examples, the machine learning prediction model may include multiple models configured to perform one or more different stages of a prediction process.

In some embodiments, the machine learning prediction model is trained using time-series data. By way of example, a machine learning prediction model may include a bi-directional LSTM with one or more attention layers. The bi-directional LSTM may be trained to generate one or more time-series embeddings from the time-series data for prediction modeling. One or more supervised prediction models (e.g., support vector machines, neural networks, random forests, etc.) may be trained, using one or more supervised training techniques (e.g., back propagation of errors, etc.) to generate parameter risk scores 304 based on the time-series embeddings and/or a labelled training dataset.

In some embodiments, a projected parameter rate is a predicted parameter rate 316 that is augmented to provide one or more rate visualizations, for example, through the user interface 312. For instance, the predicted parameter rate 316 may be leveraged to generate a projected parameter rate that projects to one or more future time intervals and/or time increments of a current and/or future time interval. In this manner, the predicted parameter rate 316 may enable forecasting of one or more predictive insights (e.g., disease burden in a clinical domain, etc.) to a future time interval and/or one or more time increments of a current and/or future time interval.

By way of example, the predicted parameter rate 316 may be broken up into a plurality of time increments (e.g., monthly subcomponents of a year, etc.) that aggregate to the high-level estimate for the entire time interval. This data may then allow for better glide path projection and allow for enhanced granularity in terms of specific cohort projections.

In some embodiments, a predicted parameter rate 316 is generated for the entity cohort 308 based on the plurality of entity-specific parameter scores 306 for the entity cohort 308. In some examples, the predicted parameter rate 316 is generated by aggregating the plurality of entity-specific parameter scores 306. For example, the predicted parameter rate 316 may include a mean entity-specific parameter score of the plurality of entity-specific parameter scores 306.

In some embodiments, the predicted parameter rate 316 is a data value that describes a predicted rate at which a parameter of interest is present within the entity cohort 308. A predicted parameter rate 316, for example, may include a percentage, ratio, and/or the like of an entity cohort 308 that is predicted to be associated with a parameter of interest within a time interval, such as a month, year, and/or the like. By way of example, the predicted parameter rate 316 may correspond to a time interval of interest. In some examples, the time interval of interest may include a plurality of time increments (e.g., months within a year, etc.). In some examples, the predicted parameter rate 316 may be generated for a time interval (e.g., a year) and then allocated to a plurality of time increments (e.g., months, etc.) to forecast a glide path at a time increment level.

The predicted parameter rate 316 may depend on a parameter of interest and/or prediction domain. As one example, in a clinical domain, a parameter of interest may include a disease and/or category of diseases, such as one or more diseases characterized by an HCC code. In such a case, the predicted parameter rate 316 may include a ratio of entities (e.g., members of a healthcare system) that are expected to be diagnosed with the HCC code within a time interval (and/or time increment thereof). By way of example, the predicted parameter rate 316 may be derived from the documented parameter rate 314, one or more historical attributes for the entity cohort 308, one or more predictive models, and/or the like.

In some embodiments, the predicted parameter rate 316 is generated based on a plurality of entity-specific parameter scores 306 for each entity of the entity cohort 308. For instance, the predicted parameter rate 316 may be aggregated from a plurality of individual entity-specific parameter scores 306. In this manner, the predicted parameter rate 316 may be stratified into a plurality of different population metrics for different population sizes in an interactive manner.

In some embodiments, a predicted documentation error 322 is generated for the entity cohort 308 based on a comparison between the documented parameter rate 314 and the predicted parameter rate 316.

In some embodiments, the predicted documentation error 322 is a data value that describes a predicted under representation of a parameter of interest within the entity cohort 308. For instance, the predicted documentation error 322 may be based on one or more differences between the documented parameter rate 314 and/or the predicted parameter rate 316 for the entity cohort 308. The predicted documentation error 322, for example, may be based on a comparison between the documented parameter rate 314 and/or the predicted parameter rate 316 for the entity cohort 308. By way of example, the predicted documentation error 322 may include a distance between the documented parameter rate 314 and/or the predicted parameter rate 316 for the entity cohort 308.

In some embodiments, the performance of an error correction action is initiated for the entity cohort 308 in response to the predicted documentation error 322. In some examples, the error correction action may be initiated in response to the predicted documentation error 322 exceeding an error threshold.

In some embodiments, the error correction action is a prediction-based action that may be selected to decrease a predicted documentation error 322 for an entity cohort 308. For example, the error correction action may be selected from a plurality of potential error correction actions 320 for the entity cohort 308. In some examples, the error correction action may be selected in response to the predicted documentation error 322 exceeding an error threshold. In some examples, the error correction action may be selected based on selection input. The error correction action, for example, may include an optimal clinical measure for the entity cohort 308 within a clinical domain.

In some embodiments, the error threshold is a data value that describes documentation criteria for the entity cohort 308. The error threshold, for example, may be a real number, percentage, probability, and/or the like that describes an acceptable predicted documentation error 322. By way of example, the error threshold may include a percentage threshold, such as a 3%, 5%, 10%, and/or the like, which describes an acceptable ratio of under documented parameters of interest within the entity cohort 308. In some examples, the error threshold may be cohort specific. For instance, the error threshold may be a function of a geographic region, one or more region attributes (e.g., rural/urban, healthcare accessibility, etc.), one or more entity attributes (e.g., average demographics such as age, etc.), one or more cohort attributes (e.g., a number of entities within the entity cohort 308, etc.), and/or the like. In addition, or alternatively, the error threshold may be cohort generic. For instance, a static error threshold may be applied to each of a plurality of different entity cohorts 308.

In some embodiments, the error correction action is identified and/or initiated using one or more cohort-specific causal models 318. For example, each of the one or more cohort-specific causal models 318 may correspond to the entity cohort 308 and a respective error correction action of one or more potential error correction actions 320 for the entity cohort 308. In some examples, the error correction action may be selected from the one or more potential error correction actions 320. For instance, one or more respective simulated error correction outcomes may be generated, using the one or more cohort-specific causal models 318, for the one or more potential error correction actions 320. The error correction action may be selected based on the one or more respective simulated error correction outcomes.

In some embodiments, the potential error correction actions 320 are one or more potential prediction-based actions for the entity cohort 308. For example, the one or more potential error correction actions 320 may include one or more processes, programs, actions, and/or sequences thereof that may be implemented for the entity cohort 308 to improve the documented parameter rate 314. The potential error correction actions 320 may depend on a prediction domain. As some examples, in a clinical domain, the potential error correction actions 320 may include one or more house call programs to improve house call penetration, primary care provider (PCP) engagement incentive programs, clinical interventions, healthcare campaigns, and/or the like.

In some embodiments, the cohort-specific causal model 318 is a data construct that describes one or more causal relationships within one or more entity cohorts 308. For example, the cohort-specific causal model may refer to, or include, parameters, hyperparameters, and/or defined operations of a causal model that is configured to generate one or more nonlinear causal impact predictions of one or more causal variables on a predictive outcome associated with entities of one or more entity cohorts 308. One or more causal variables, for example, may include entity attributes associated with one or entity data objects 310 corresponding to the entity cohort 308. In some examples, nonlinear causal impact predictions may be based on historical data and/or one or more knowledge graphs associated with a prediction domain. The cohort-specific causal model 318, for example, may include a directed acyclic graph (DAG) that defines one or more causal relationships between the one or more entity attributes and a predictive outcome. A predictive outcome, for example, may include a prediction that an entity will be documented with a parameter of interest (e.g., thereby improving the documented parameter rate 314 of the entity cohort 308) in response to a potential error correction action.

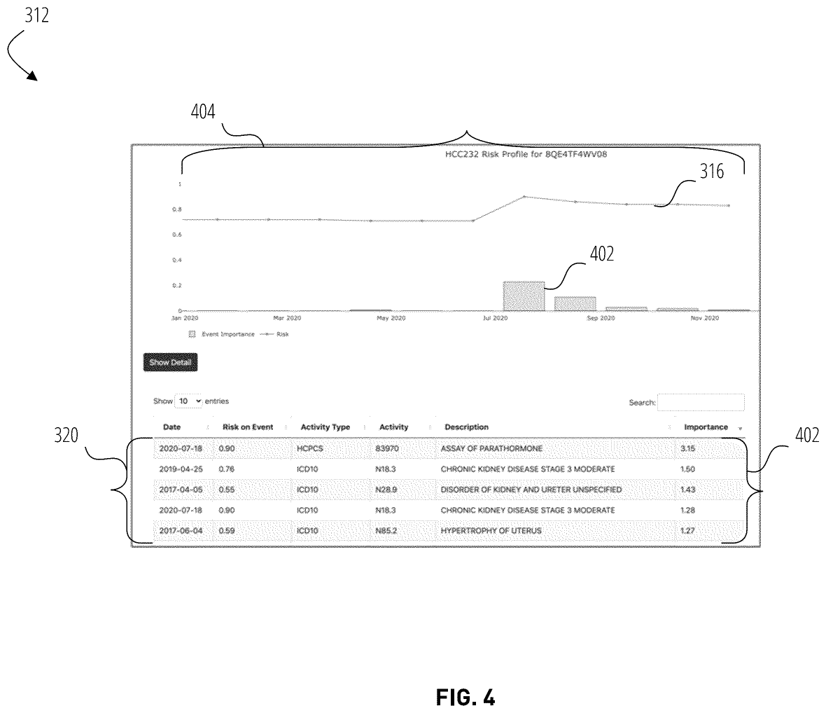

In some embodiments, an error correction action is selected from the potential error correction actions 320 based one or more simulated predictive insights from the cohort-specific causal models 318. The predictive insights, for example, may be overlaid on a user interface 312. By doing so, a user may interact with a single, comprehensive user interface to seamlessly evaluate entity cohorts 308 of varying sizes, locations, and complexities. An example user interface 312 will now further be described with reference to FIG. 4.

FIG. 4 is an exemplary diagram of a user interface 312 in accordance with some embodiments discussed herein. The exemplary diagram depicts an example predictive insights screen of the user interface 312. As depicted, the user interface 312 may represent one or more predictive metrics for an entity cohort including, as examples, a predicted parameter rate 316 over a time interval 404 and a plurality of simulated error correction outcomes 402 for a plurality of potential error correction actions 320.

In some examples, the simulated error correction outcomes 402 may be generated, using one or more cohort-specific causal models, for the potential error correction actions 320. The simulated error correction outcome 402 may be generated automatically and/or in response to a selection input. As shown, a plurality of simulated error correction outcomes 402 may be generated for one or more times within the time interval 404 to evaluate a potential impact of one or more potential error correction actions 320, individually and/or in combination.

For example, the cohort-specific causal models may include intervention predictive models that enable an understanding of a potential impact of one or more potential error correction actions 320 on a documented parameter rate of the entity cohort with respect to the predicted parameter rate 316. In some examples, the cohort-specific causal models may provide a cause/effect multi-input/single-output capability that may be overlayed, within the user interface 312, to documentation insights for the entity cohort to statistically evaluate various potential error correction actions 320 for the entity cohort over time. By way of example, the cohort-specific causal models may include a multi-variate model that broadly assesses how potential error correction actions 320 with regards to programs or campaigns within the entity cohort may impact predicted documentation errors with respect to the predicted parameter rate 316.

In some embodiments, the cohort-specific causal models are configured to output an entity-specific impact prediction for each entity within the entity cohort. Each entity-specific impact prediction may describe a likelihood that a respective entity of an entity cohort will be documented with a parameter of interest in response to one or more potential error correction actions 320. In some examples, a simulated error correction outcome 402 may be generated by aggregating the entity-specific impact predictions for one or more entities within the entity cohort. In addition, or alternatively, the cohort-specific causal models may be configured to output the simulated error correction outcomes 402.

In some embodiments, the simulated error correction outcomes 402 are data values that describe an expected increase in a documented parameter rate for an entity cohort in response to an error correction action. The simulated error correction outcome 402, for example, may be a real number, percentage, probability, and/or the like that describes an estimated change in a document parameter rate. By way of example, the simulated error correction outcomes 402 may include a percentage increases, such as a 3%, 5%, 10%, and/or the like, which describes a simulated outcome of an implementation of an error correction action with respect to an entity cohort.

In some examples, as illustrated by FIG. 4, the simulated error correction outcomes 402 may be ranked based on an importance value. An importance value, for example, may be assigned based on the relative magnitude of each of the simulated error correction outcome 402 and/or one or more contextual attributes, such as a granular documentation increase (e.g., for a sub-category of a parameter of interest, etc.), an activity type, and/or the like.

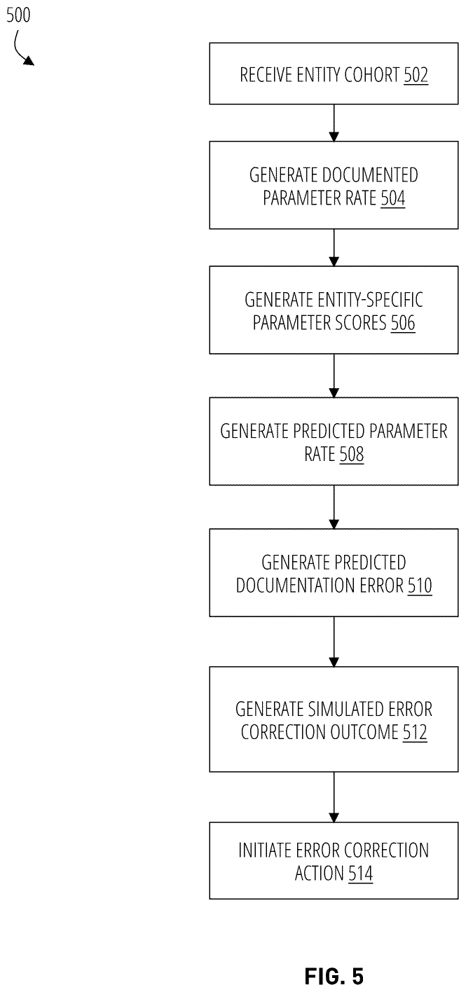

FIG. 5 is a flowchart showing an example of an entity cohort evaluation process 500 in accordance with some embodiments discussed herein. The flowchart depicts an evaluation process 500 for improving the predictive assessment, visualization, and control of a documentation efficiencies with respect to traditional population tracking techniques. The process 500 may be implemented by one or more computing devices, entities, and/or systems described herein. For example, via the various steps/operations of the process 500, the computing system 100 may leverage improved predictive modeling and simulation techniques to generate interactive cohort insights that are both comprehensive and uniquely tailored to dynamically sized entity cohorts of various and changing size ranges within a prediction domain. By doing so, the process 500 enables the real time and interactive analysis of population-based predictive metrics that empower the initiation of prediction-based actions tailored and optimized for specific segments of a population. By way of example, unlike traditional population tracking techniques, the evaluation techniques implemented by the process 500 may be capable of generating cohort insights from granular, entity-level predictions that may be stratified into dynamically changing cohort sizes. These, in turn, may enable interactive entity-level simulations to generate optimized actions for an entity cohort.

FIG. 5 illustrates an example process 500 for explanatory purposes. Although the example process 500 depicts a particular sequence of steps/operations, the sequence may be altered without departing from the scope of the present disclosure. For example, some of the steps/operations depicted may be performed in parallel or in a different sequence that does not materially impact the function of the process 500. In other examples, different components of an example device or system that implements the process 500 may perform functions at substantially the same time or in a specific sequence.

In some embodiments, the process 500 includes, at step/operation 502, receiving an entity cohort. For example, the computing system 100 may receive entity cohort criteria defining an entity cohort. In some examples, the entity cohort may be selected based on a selection input to a user interface.

In some embodiments, the process 500 includes, at step/operation 504, generate a documented parameter rate. For example, the computing system 100 may generate a documented parameter rate for the entity cohort.

In some embodiments, the process 500 includes, at step/operation 506, generate an entity-specific parameter score. For example, the computing system 100 may generate, using a machine learning prediction model, a plurality of entity-specific parameter scores for the entity cohort. In some examples, the plurality of entity-specific parameter scores may include a respective parameter risk score for each of a plurality of entity data objects within the entity cohort. For instance, the machine learning prediction model may be previously trained to generate a parameter risk score based on one or more entity attributes and the respective parameter risk score may be based on one or more respective entity attributes of a respective entity data object within the entity cohort. In some examples, the parameter risk score includes a value between zero and one.

In some embodiments, the process 500 includes, at step/operation 508, generate a predicted parameter rate. For example, the computing system 100 may generate a predicted parameter rate for the entity cohort based on the plurality of entity-specific parameter scores for the entity cohort. In some examples, the predicted parameter rate is generated by aggregating the plurality of entity-specific parameter scores. For example, the predicted parameter rate may include a mean entity-specific parameter score of the plurality of entity-specific parameter scores. In this manner, the predicted parameter rate may be generated based on entity-level predictions that, unlike traditional techniques, allow for entity cohorts of dynamically changing sizes and other cohort defining criteria. This enables, for example, the generation of interactive cohorts based on user input.

In some embodiments, the process 500 includes, at step/operation 510, generate a predicted documentation error. For example, the computing system 100 may generate a predicted documentation error for the entity cohort based on a comparison between the documented parameter rate and the predicted parameter rate. In some examples, the predicted documentation error may be generated in response to the selection input.

In some embodiments, the process 500 includes, at step/operation 512, generate a simulated error correction outcome. For example, the computing system 100 may generate, using one or more cohort-specific causal models, one or more respective simulated error correction outcomes for one or more potential error correction actions. For example, each of the one or more cohort-specific causal models may correspond to the entity cohort and a respective error correction action of one or more potential error correction actions for the entity cohort.

In some embodiments, the process 500 includes, at step/operation 514, initiate error correction action. For example, the computing system 100 may, responsive to the predicted documentation error, initiate, using one or more cohort-specific causal models, the performance of an error correction action for the entity cohort. For instance, the computing system 100 may initiate the performance of the error correction action for the entity cohort by selecting the error correction action from the one or more potential error correction actions. In some examples, the computing system 100 may select the error correction action based on the one or more respective simulated error correction outcomes. In some examples, the error correction action is initiated in response to the predicted documentation error exceeding an error threshold.

Some techniques of the present disclosure enable the generation of action outputs that may be performed to initiate one or more prediction-based actions to achieve real-world effects. The computer interpretation techniques of the present disclosure may be used, applied, and/or otherwise leveraged to generate various predictions, such as entity-specific parameter scores, predictive parameter rates, simulated error correction outcome, among others, which may help in the computer forecasting and simulation of variably sized populations. The predictive insights of the present disclosure may be leveraged to initiate the performance of various computing tasks that improve the performance of a computing system (e.g., a computer itself, etc.) with respect to various prediction-based actions performed by the computing system 100, such as for the initiation of error correction actions and/or the like. Example prediction-based actions may include the automatic initiation of error correction actions tailored to a particular entity cohort, and/or the like.

In some examples, the computing tasks may include prediction-based actions that may be based on a prediction domain. A prediction domain may include any environment in which computing systems may be applied to achieve real-word insights, such as those described herein, and initiate the performance of computing tasks, such as prediction-based actions to act on the real-world insights (e.g., derived from predictions describe herein, etc.). These prediction-based actions may cause real-world changes, for example, by controlling a hardware component, providing alerts, interactive actions, and/or the like.

Examples of search domains may include financial systems, clinical systems, autonomous systems, robotic systems, and/or the like. Prediction-based actions in such domains may include the initiation of automated instructions across and between devices, automated notifications, automated scheduling operations, automated precautionary actions, automated security actions, automated data processing actions, and/or the like.

### VI. Conclusion

Many modifications and other embodiments will come to mind to one skilled in the art to which the present disclosure pertains having the benefit of the teachings presented in the foregoing descriptions and the associated drawings. Therefore, it is to be understood that the present disclosure is not to be limited to the specific embodiments disclosed and that modifications and other embodiments are intended to be included within the scope of the appended claims. Although specific terms are employed herein, they are used in a generic and descriptive sense only and not for purposes of limitation.

### VII. EXAMPLES

Example 1. A computer-implemented method, the computer-implemented method comprising generating, by one or more processors, a documented parameter rate for an entity cohort; generating, by the one or more processors and using a machine learning prediction model, a plurality of entity-specific parameter scores for the entity cohort; generating, by the one or more processors, a predicted parameter rate for the entity cohort based on the plurality of entity-specific parameter scores for the entity cohort; generating, by the one or more processors, a predicted documentation error for the entity cohort based on a comparison between the documented parameter rate and the predicted parameter rate; and responsive to the predicted documentation error, initiating, by the one or more processors and using one or more cohort-specific causal models, the performance of an error correction action for the entity cohort.

Example 2. The computer-implemented method of example 1, wherein the plurality of entity-specific parameter scores comprises a respective parameter risk score for each of a plurality of entity data objects within the entity cohort.

Example 3. The computer-implemented method of example 2, wherein the machine learning prediction model is previously trained to generate a parameter risk score based on one or more entity attributes and the respective parameter risk score is based on one or more respective entity attributes of a respective entity data object within the entity cohort.

Example 4. The computer-implemented method of examples 1 or 2, wherein the parameter risk score comprises a value between zero and one.

Example 5. The computer-implemented method of any of the preceding examples, wherein the predicted parameter rate is generated by aggregating the plurality of entity-specific parameter scores.

Example 6. The computer-implemented method of example 5, wherein the predicted parameter rate comprises a mean entity-specific parameter score of the plurality of entity-specific parameter scores.

Example 7. The computer-implemented method of any of the preceding examples, wherein the error correction action is initiated in response to the predicted documentation error exceeding an error threshold.

Example 8. The computer-implemented method of any of the preceding examples, wherein each of the one or more cohort-specific causal models correspond to the entity cohort and a respective error correction action of one or more potential error correction actions for the entity cohort.

Example 9. The computer-implemented method of example 8, wherein initiating the performance of the error correction action for the entity cohort comprises selecting the error correction action from the one or more potential error correction actions.

Example 10. The computer-implemented method of example 9, wherein selecting the error correction action comprises generating, using the one or more cohort-specific causal models, one or more respective simulated error correction outcomes for the one or more potential error correction actions; and selecting the error correction action based on the one or more respective simulated error correction outcomes.

Example 11. The computer-implemented method of any of the preceding examples, wherein the entity cohort is selected based on a selection input to a user interface and the predicted documentation error is generated in response to the selection input.

Example 12. A computing system comprising memory and one or more processors communicatively coupled to the memory, the one or more processors configured to generate a documented parameter rate for an entity cohort; generate, using a machine learning prediction model, a plurality of entity-specific parameter scores for the entity cohort; generate a predicted parameter rate for the entity cohort based on the plurality of entity-specific parameter scores for the entity cohort; generate a predicted documentation error for the entity cohort based on a comparison between the documented parameter rate and the predicted parameter rate; and responsive to the predicted documentation error, initiate, using one or more cohort-specific causal models, the performance of an error correction action for the entity cohort.

Example 13. The computing system of example 12, wherein the plurality of entity-specific parameter scores comprises a respective parameter risk score for each of a plurality of entity data objects within the entity cohort.

Example 14. The computing system of examples 12 or 13, wherein the machine learning prediction model is previously trained to generate a parameter risk score based on one or more entity attributes and the respective parameter risk score is based on one or more respective entity attributes of a respective entity data object within the entity cohort.

Example 15. The computing system of examples 13 or 14, wherein the parameter risk score comprises a value between zero and one.

Example 16. The computing system of example 12, wherein the predicted parameter rate is generated by aggregating the plurality of entity-specific parameter scores.

Example 17. The computing system of example 16, wherein the predicted parameter rate comprises a mean entity-specific parameter score of the plurality of entity-specific parameter scores.

Example 18. The computing system of any of examples 12 through 17, wherein the error correction action is initiated in response to the predicted documentation error exceeding an error threshold.

Example 19. One or more non-transitory computer-readable storage media including instructions that, when executed by one or more processors, cause the one or more processors to generate a documented parameter rate for an entity cohort; generate, using a machine learning prediction model, a plurality of entity-specific parameter scores for the entity cohort; generate a predicted parameter rate for the entity cohort based on the plurality of entity-specific parameter scores for the entity cohort; generate a predicted documentation error for the entity cohort based on a comparison between the documented parameter rate and the predicted parameter rate; and responsive to the predicted documentation error, initiate, using one or more cohort-specific causal models, the performance of an error correction action for the entity cohort.

Example 20. The one or more non-transitory computer-readable storage media of example 19, wherein each of the one or more cohort-specific causal models correspond to the entity cohort and a respective error correction action of one or more potential error correction actions for the entity cohort.

1. A computer-implemented method, the computer-implemented method comprising:
generating, by one or more processors, a documented parameter rate for an entity cohort;
generating, by the one or more processors and using a machine learning prediction model, a plurality of entity-specific parameter scores for the entity cohort;
generating, by the one or more processors, a predicted parameter rate for the entity cohort based on the plurality of entity-specific parameter scores for the entity cohort;
generating, by the one or more processors, a predicted documentation error for the entity cohort based on a comparison between the documented parameter rate and the predicted parameter rate; and
responsive to the predicted documentation error, initiating, by the one or more processors and using one or more cohort-specific causal models, the performance of an error correction action for the entity cohort.

2. The computer-implemented method of claim 1, wherein the plurality of entity-specific parameter scores comprises a respective parameter risk score for each of a plurality of entity data objects within the entity cohort.

3. The computer-implemented method of claim 2, wherein the machine learning prediction model is previously trained to generate a parameter risk score based on one or more entity attributes and the respective parameter risk score is based on one or more respective entity attributes of a respective entity data object within the entity cohort.

4. The computer-implemented method of claim 2, wherein the parameter risk score comprises a value between zero and one.

5. The computer-implemented method of claim 1, wherein the predicted parameter rate is generated by aggregating the plurality of entity-specific parameter scores.

6. The computer-implemented method of claim 5, wherein the predicted parameter rate comprises a mean entity-specific parameter score of the plurality of entity-specific parameter scores.

7. The computer-implemented method of claim 1, wherein the error correction action is initiated in response to the predicted documentation error exceeding an error threshold.

8. The computer-implemented method of claim 1, wherein each of the one or more cohort-specific causal models correspond to the entity cohort and a respective error correction action of one or more potential error correction actions for the entity cohort.

9. The computer-implemented method of claim 8, wherein initiating the performance of the error correction action for the entity cohort comprises selecting the error correction action from the one or more potential error correction actions.

10. The computer-implemented method of claim 9, wherein selecting the error correction action comprises:
generating, using the one or more cohort-specific causal models, one or more respective simulated error correction outcomes for the one or more potential error correction actions; and
selecting the error correction action based on the one or more respective simulated error correction outcomes.

11. The computer-implemented method of claim 1, wherein the entity cohort is selected based on a selection input to a user interface and the predicted documentation error is generated in response to the selection input.

12. A computing system comprising memory and one or more processors communicatively coupled to the memory, the one or more processors configured to:
generate a documented parameter rate for an entity cohort;
generate, using a machine learning prediction model, a plurality of entity-specific parameter scores for the entity cohort;
generate a predicted parameter rate for the entity cohort based on the plurality of entity-specific parameter scores for the entity cohort;
generate a predicted documentation error for the entity cohort based on a comparison between the documented parameter rate and the predicted parameter rate; and
responsive to the predicted documentation error, initiate, using one or more cohort-specific causal models, the performance of an error correction action for the entity cohort.

13. The computing system of claim 12, wherein the plurality of entity-specific parameter scores comprises a respective parameter risk score for each of a plurality of entity data objects within the entity cohort.

14. The computing system of claim 12, wherein the machine learning prediction model is previously trained to generate a parameter risk score based on one or more entity attributes and the respective parameter risk score is based on one or more respective entity attributes of a respective entity data object within the entity cohort.

15. The computing system of claim 13, wherein the parameter risk score comprises a value between zero and one.

16. The computing system of claim 12, wherein the predicted parameter rate is generated by aggregating the plurality of entity-specific parameter scores.

17. The computing system of claim 16, wherein the predicted parameter rate comprises a mean entity-specific parameter score of the plurality of entity-specific parameter scores.

18. The computing system of claim 12, wherein the error correction action is initiated in response to the predicted documentation error exceeding an error threshold.

19. One or more non-transitory computer-readable storage media including instructions that, when executed by one or more processors, cause the one or more processors to:
generate a documented parameter rate for an entity cohort;
generate, using a machine learning prediction model, a plurality of entity-specific parameter scores for the entity cohort;
generate a predicted parameter rate for the entity cohort based on the plurality of entity-specific parameter scores for the entity cohort;
generate a predicted documentation error for the entity cohort based on a comparison between the documented parameter rate and the predicted parameter rate; and
responsive to the predicted documentation error, initiate, using one or more cohort-specific causal models, the performance of an error correction action for the entity cohort.

20. The one or more non-transitory computer-readable storage media of claim 19, wherein each of the one or more cohort-specific causal models correspond to the entity cohort and a respective error correction action of one or more potential error correction actions for the entity cohort.
